(19) United States
(12) Patent Application Publication
(10) Pub. No.: US 2020/0066520 A1
(43) Pub. Date: Feb. 27, 2020

(54) ALTERNATING HARD MASK FOR TIGHT-PITCH FIN FORMATION

(71) Applicant: International Business Machines Corporation, Armonk, NY (US)

(72) Inventors: JOHN C. ARNOLD, North Chatham, NY (US); SEAN BURNS, HOPEWELL JUNCTION, NY (US); NELSON FELIX, Slingerlands, NY (US); CHI-CHUN LIU, Altamont, NY (US); YANN MIGNOT, Slingerlands, NY (US); STUART A. SIEG, Albany, NY (US)

(21) Appl. No.: 16/109,109

(22) Filed: Aug. 22, 2018

(51) Int. Cl. H01L 21/033; H01L 21/311; H01L 21/308; H01L 21/027; H01L 27/088; G03F 7/00

(52) U.S. Cl. CPC H01L 21/0337; H01L 21/31144; G03F 7/0002; H01L 21/0273; H01L 27/0886; H01L 21/3086

(57) ABSTRACT

A wafer element with a tight-pitch formation is provided. The wafer element includes an alternating material hard mask comprising a repeating array of abutting first, second and third vertical elements. The first, second and third vertical elements are formed of first, second and third materials, respectively. The first material is selectively etchable with respect to the second and third materials, the second material is selectively etchable with respect to the first and third materials and the third material is selectively etchable with respect to the first and second materials.

### BACKGROUND

The present invention generally relates to semiconductor device fabrication methods and resulting structures. More specifically, the present invention relates to forming the fins of non-planar field effect transistor (FET) architectures using an alternating hard mask for tight-pitch fin formation process based on directed self-assembly (DSA), self-aligned double patterning (SADP) generated guiding patterns, and sequential infiltration synthesis.

A fin-type field-effect transistor (FinFET) is a metal-oxide-semiconductor field effect transistor (MOSFET) that is built on a substrate where a gate is placed on two, three or four sides of a fin-shaped channel or wrapped around the channel, to form a double gate structure. The source and drain regions are the portions of the fin that are not covered by the gate structure.

### SUMMARY

Embodiments of the present invention are directed to a wafer element with a tight-pitch formation. A non-limiting example of the wafer element with the tight-pitch formation includes an alternating material hard mask. The alternating material hard mask includes a repeating array of abutting first, second and third vertical elements. The first, second and third vertical elements are formed of first, second and third materials, respectively. The first material is selectively etchable with respect to the second and third materials, the second material is selectively etchable with respect to the first and third materials and the third material is selectively etchable with respect to the first and second materials.

Embodiments of the present invention are directed to a method of fabricating a wafer element with a tight-pitch formation. A non-limiting example of the method includes assembling an initial structure. The initial structure includes an alternating material hard mask stack, a fin array and a spacer material disposed over the fin array. The method further includes executing a self-aligned double patterning (SADP) process on the initial structure to produce a guide pattern for a directed self-assembly process (DSA) and executing the DSA process from the guide pattern to produce a first repeating array of abutting first and second vertical elements with critical dimension uniformity. The method also includes synthesizing a second repeating array of abutting first, second and third vertical elements from the first repeating array.

Embodiments of the invention are directed to a method of fabricating a wafer element with a tight-pitch formation. A non-limiting example of the method includes assembling an initial structure. The initial structure includes an alternating material hard mask stack, a fin array and a spacer material disposed over the fin array. The method further includes executing a self-aligned double patterning (SADP) process on the initial structure to produce a first intermediate structure. The first intermediate structure includes vertical elements and the vertical elements include vertical portions of the spacer material and corresponding portions of the alternating hard mask stack. The method further includes executing a directed self-assembly (DSA) process on the first intermediate structure to produce a second intermediate structure. The second intermediate structure includes a first repeating array of abutting first and second vertical elements. The method also includes synthesizing a second repeating array of abutting first, second and third vertical elements from the second intermediate structure.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a schematic side view of a wafer element in accordance with embodiments of the present invention;

FIG. 2 depicts a spacer deposition onto the wafer element of FIG. 1 in accordance with embodiments of the present invention;

FIG. 3 depicts the wafer element of FIG. 2 following spacer etch back, mandrel pull and breakthrough operations in accordance with embodiments of the present invention;

FIG. 4 depicts the wafer element of FIG. 3 following a selective oxide breakthrough operation in accordance with embodiments of the present invention;

FIG. 5 depicts the wafer element of FIG. 4 following a brush coating operation in accordance with embodiments of the present invention;

FIG. 6 depicts the wafer element of FIG. 5 following a spacer pull operation by diluted hydrofluoric acid (dHF) or chemical oxide removal (COR) in accordance with embodiments of the present invention;

FIG. 7 depicts the wafer element of FIG. 6 following an excess brush rinse operation in accordance with embodiments of the present invention;

FIG. 8 depicts the wafer element of FIG. 7 following a directed self-assembly operation in accordance with embodiments of the present invention;

FIG. 9 depicts the wafer element of FIG. 8 following a sequential infiltration synthesis operation in accordance with embodiments of the present invention;

FIG. 10 depicts the wafer element of FIG. 9 following an etch operation in accordance with embodiments of the present invention;

FIG. 11 depicts the wafer element of FIG. 10 following an organic planarization layer formation and recession in accordance with embodiments of the present invention;

FIG. 12 depicts the wafer element of FIG. 11 following stripping and cleaning operations in accordance with embodiments of the present invention;

FIG. 13 depicts the wafer element of FIG. 12 following etch operations in accordance with embodiments of the present invention;

FIG. 14 depicts the wafer element of FIG. 13 following the formation of an oxide layer and subsequent polishing and oxide removal operations in accordance with embodiments of the present invention; and

FIG. 15 depicts the wafer element of FIG. 14 following lithographic operations in accordance with embodiments of the present invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted that the term “selective to,” such as, for example, “a first element selective to a second element,” means that the first element can be etched and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device having a dummy tin removed from within an array of tight pitch tins according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the invention, the fabrication of FinFET semiconductor structures having a single dummy fin removed from within an array of tight pitch fins requires a lithographically patterned mask to physically expose the unwanted dummy semiconductor fin while covering and protecting the adjacent semiconductor fins. The lithographically patterned mask includes two sidewalls of a patterned photoresist that need to be positioned within the spaces between the single dummy semiconductor fin and the two adjacent semiconductor fins to ensure that only the single dummy fin is removed without removing any additional semiconductor fins. To improve device performance the semiconductor industry has repeatedly shrunk transistor gate lengths and chip sizes, increasing device density. As a consequence, fin pitch continues to shrink. Fin pitch refers to the centerline-to-centerline distance between adjacent fins. As fins are becoming closer to each other and it is becoming difficult to selectively cut a single unwanted dummy fin without compromising the adjacent device fins due to the overlay tolerances of lithographic processes. The overlay tolerances of available lithographic processes begin to limit the effective removal of a dummy fin as the fin pitch decreases in part because it is becoming increasingly difficult to precisely position the two photoresist sidewalls between adjacent fins.

Overlay error, or positioning errors, of a mask between features in the semiconductor structure can lead to reliability issues. Overlay errors result from misalignment during the lithography process as the mask invariably becomes misaligned with the underlying structure. To improve the manufacturability of lithography fabrication operations, advanced masks that incorporate phase-shifting and optical proximity correction have been employed. Although overlay errors can be mitigated by these advancements and by reworking the lithography operations, some level of overlay error is unavoidable. The issues are particularly prevalent for scales of pitch less than 30 nm (or 30P, which is described in detail below) or, even more particularly, at scales of pitch less than 20 nm (or 20P, which is described in detail below) at which edge placement errors become a substantial portion of the pitch and feature size.

Turning now to an overview of the aspects of the invention, one or more embodiments of the invention address the above-described shortcomings of the prior art by providing for a wafer element with a tight-pitch formation. The wafer element includes an alternating material hard mask. The alternating material hard mask includes a repeating array of abutting first, second and third vertical elements in a sub-30P or, more particularly, in a 25P or 20P formation. The first, second and third vertical elements are formed of first, second and third materials, respectively. The first material is selectively etchable with respect to the second and third materials, the second material being selectively etchable with respect to the first and third materials and the third material is selectively etchable with respect to the first and second materials.

The above-described aspects of the invention address the shortcomings of the prior art by implementation of alternative hard mask processing and selective etching that allows for the decomposition of sub-30P Line/Space or, more particularly, 20P Line/Space into two layer of 40P Line/Space and hence greatly increases edge placement tolerance. In addition, with a guiding pattern generated by self-aligned, double patterning (SADP), pitch and critical dimension uniformity can be controlled by directed self-assembly (DSA) processes. Also, a simplified film stack is made possible through the use of tone-inversion.

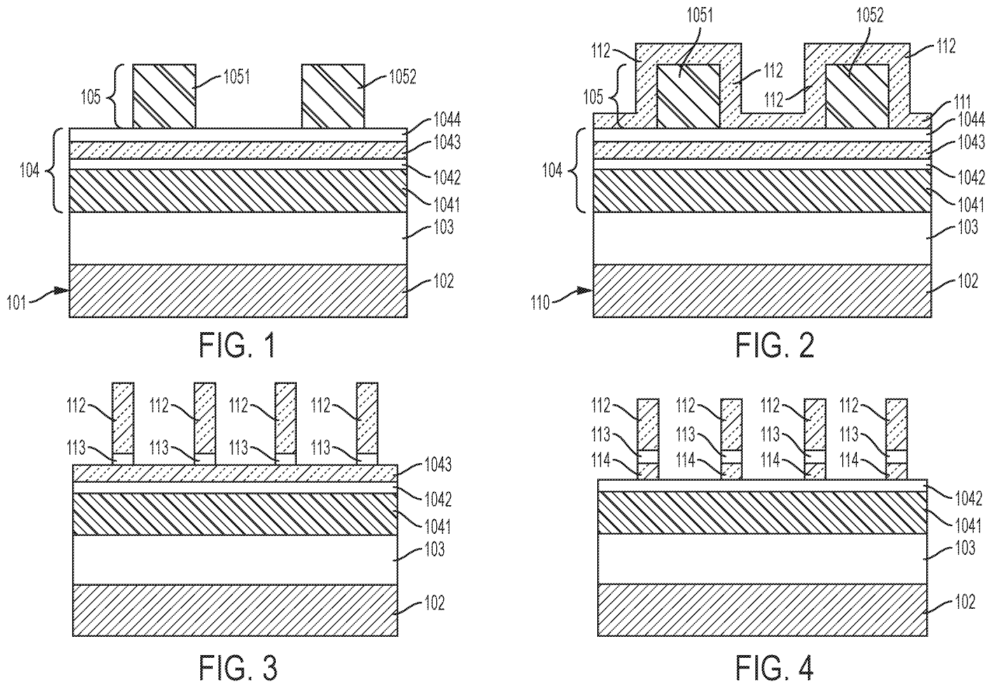

Turning now to a more detailed description of aspects of the present invention, FIG. 1 depicts a schematic side view of an initial wafer element 101 in accordance with embodiments of the present invention. The wafer element 101 includes a silicon substrate 102, a hard mask layer 103 disposed over the silicon substrate 102, an alternating material hard mask stack 104 disposed over the hard mask layer 103, and an 80 nm by 193i fin array (hereinafter referred to as a “fin array”) 105 disposed over the alternating material hard mask stack 104. The hard mask layer 103 can include a dielectric material, such as silicon nitride. The alternating material hard mask stack 104 can include a first layer 1041 of amorphous silicon, a second layer 1042 of silicon nitride that is disposed over the first layer 1041, a third layer 1043 of silicon oxide that is disposed over the second layer 1042 and a fourth layer 1044 of silicon nitride that is disposed over the second layer 1042. The fin array 105 can include a first fin element 1051 and a second fin element 1052. An edge of the first fin element 1051 can be about 80 nm from the corresponding edge of the second fin element 1052.

FIG. 2 depicts an initial structure 110 of the wafer element 101 of FIG. 1 following deposition of a spacer 111 onto the fin array 105 and the fourth layer 1044 in accordance with embodiments of the present invention. The spacer 111 can be formed of materials similar to those of the third layer 1043, such as silicon oxide, and includes lower horizontal portions that run along the fourth layer 1044, upper horizontal portions that run along uppermost surfaces of the first and second fin elements 1051 and 1052 and vertical portions 112 that extend vertical from the lower horizontal portions to the upper horizontal portions along sidewalls of the first and second fin elements 1051 and 1052.

Execution of a self-aligned double patterning (SADP) process on the initial structure 110 in order to produce a guide pattern 130 (to be described below) for a directed self-assembly process (DSA) will now be described.

FIG. 3 depicts a result of spacer etch back, mandrel pull and breakthrough operations on the initial structure 110 of FIG. 2 in accordance with embodiments of the present invention. That is, FIG. 3 illustrates that the lower and upper horizontal portions of the spacer 111 are removed along with the fin array 105 and a substantial portion of the fourth layer 1044 leaving only the vertical portions 112 and corresponding portions 113 of the fourth layer 1044 that lie under the vertical portions 112.

FIG. 4 depicts a result of a selective oxide breakthrough operation on the structure of FIG. 3 in accordance with embodiments of the present invention. That is, FIG. 4 illustrates that a substantial portion of the second layer 1042 is removed leaving only the vertical portions 112, the corresponding portions 113 of the fourth layer 1044 that lie under the vertical portions 112 and corresponding portions 114 of the third layer 1043 that lie under the corresponding portions 113 and the vertical portions 112.

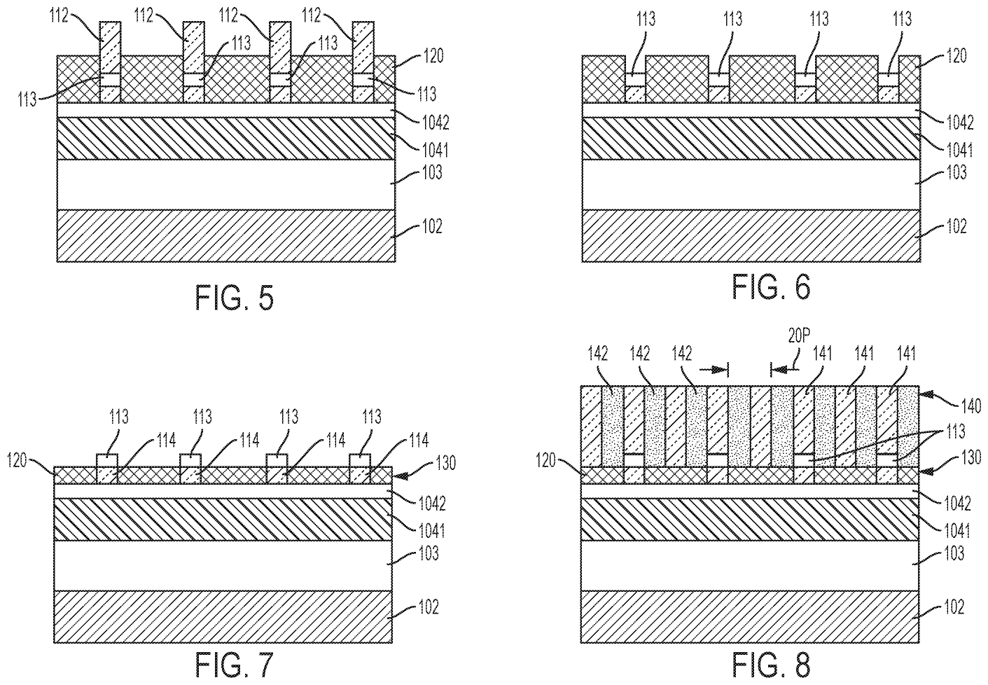

FIG. 5 depicts the structure of FIG. 4 following a brush coating and grafting operation in accordance with embodiments of the present invention. The brush coating operation produces a brush layer 120 that extends from an upper surface of the second layer 1042 to a height that is about ¼-½ the height of the vertical portions 112 as measured from respective upper surfaces of the corresponding portions 113.

FIG. 6 depicts the structure of FIG. 5 following a spacer pull operation by diluted hydrofluoric acid (dHF) or chemical oxide removal (COR) in accordance with embodiments of the present invention. As a result of the spacer pull operation, the vertical portions 112 are removed to expose the upper surfaces of the corresponding portions 113, which are recessed from an upper surface of the brush layer 120.

FIG. 7 depicts the structure of FIG. 6 following a rinse of excess layers of the brush layer 120 in accordance with embodiments of the present invention. The rinse effectively lowers the upper surface of the brush layer 120 to be roughly coplanar with the upper surfaces of the corresponding portions 114 whereupon the corresponding portions 113 protrude from the upper surface of the brush layer 120. The upper surface of the brush layer 120 can be taller than the corresponding portions 114 but cannot be taller than the corresponding portions 113. Because the brush polymer of the brush layer 120 forms a monolayer after rinsing, the thickness of the grafted brush layer 120 can be adjusted by the molecular weight and grafting density. This forms the guide pattern 130.

Execution of the DSA process on the guide pattern 130 to generate a first repeating array 140 (to be described below) will now be described.

FIG. 8 depicts the guide pattern 130 of FIG. 7 following execution of a DSA process with respect to the guide pattern 130 in accordance with embodiments of the present invention. As a result of the execution of the DSA process, the first repeating array 140 is produced. The first repeating array 140 includes first vertical elements 141 and second vertical elements 142 interleaved with the first vertical elements 141. The first vertical elements 141 are formed of polymethyl methacrylate (PMMA) and the second vertical elements 142 are formed of polystyrene (PS). Other block copolymer systems, such as PS-poly vinyl pyridine (PVP) and PMMA-b-PVP, can be applied here as well. A portion of the first vertical elements 141 extend vertically from upper surfaces of the corresponding portions 113 and have widths which correspond to the widths of the corresponding portions 113. The second vertical elements 142 extend vertically from upper surfaces of the brush layer 120 along edges of the corresponding portions 113 and have widths which correspond to the widths of the first vertical elements 141. The spaces between proximal second vertical elements are filled with another portion of the first vertical elements 141 which extend vertically from the upper surfaces of the brush layer 120 and have widths which correspond to the widths of the second vertical elements 142.

Thus, as shown in FIG. 8, each first vertical element 141 abuts in a side-by-side arrangement with two second vertical elements 142 and the first repeating array 140 has a sub-30P or, more particularly, a 20P formation with improved critical dimension (CD) uniformity as compared to the guide pattern 130. That is, an edge of one of the first vertical elements 141 is less than 30 nm or, more particularly, 20 nm from an opposite edge of a neighboring second vertical element 142.

Execution of a synthesis of a second repeating array 170 of abutting first, second and third vertical elements in a sub-30P or, more particularly, in a 20P formation from the first repeating array 140 will now be described.

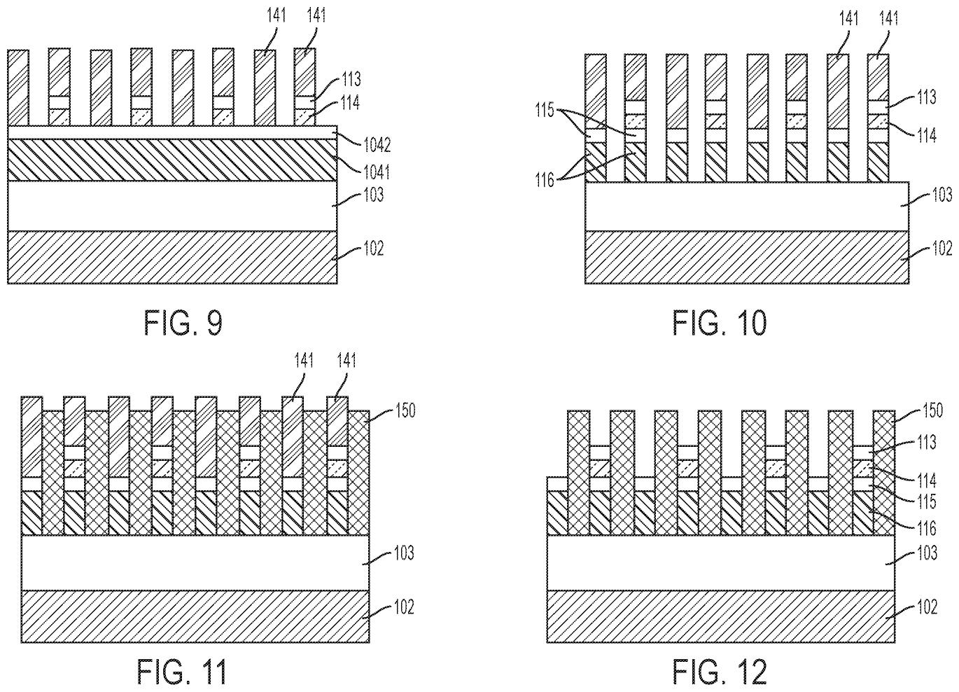

FIG. 9 depicts the first repeating array 140 of FIG. 8 following a sequential infiltration synthesis operation in accordance with embodiments of the present invention. The sequential infiltration process involves the transformation of the first vertical elements 141 into aluminum oxide. The unaffected second vertical elements 142, which are still made of organic polymeric material, are then removed by an oxygen plasma etch to expose the second layer 1042. This is, in some cases, followed by a trim etch to rectify the CD of the corresponding portions 113 and 114.

FIG. 10 depicts a result of an etch operation executed on the structure of FIG. 9 in accordance with embodiments of the present invention. As a result of the etch operation, substantial portions of the second and first layers 1042 and 1041 are removed. This exposes an upper surface of the hard mask layer 103 and leaves corresponding portions 115 and 116 of the second and first layers 1042 and 1041 lying under the first vertical elements 141 (now formed of aluminum oxide) and the corresponding portions 113 and 114 or just the first vertical elements 141 (now formed of aluminum oxide).

FIG. 11 depicts the structure of FIG. 10 following formation of an organic planarization layer (OPL) 150 and a recession of the OPL 150 in accordance with embodiments of the present invention. After this over-coating and etch back of the OPL 150, the OPL 150 extends upwardly from the upper surface of the hard mask layer 103 and terminates shy of upper supper surfaces of the first vertical elements 141 such that the first vertical elements 141 protrude above an upper surface of the OPL 150.

FIG. 12 depicts the structure of FIG. 11 following stripping and cleaning operations in accordance with embodiments of the present invention. The stripping and cleaning operations result in the removal of the first vertical elements 141 and exposes the silicon nitride of the corresponding portions 113 and the silicon nitride of the corresponding portions 115.

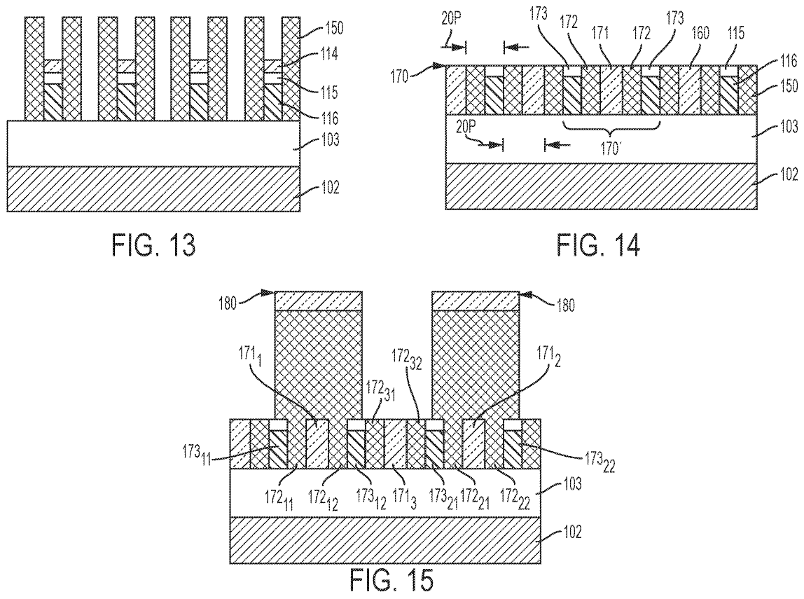

FIG. 13 depicts the structure of FIG. 12 following etch operations in accordance with embodiments of the present invention. The etch operations remove the silicon nitride of the corresponding portions 113 to expose the silicon oxide of the corresponding portions 114 and remove the silicon nitride of the corresponding portions 115 to expose the amorphous silicon of the corresponding portions 116. The etch operations further remove the amorphous silicon of the corresponding portions 116 to re-expose upper surfaces of the hard mask layer 103.

FIG. 14 depicts the formation of an oxide layer 160 on the structure of FIG. 13 and subsequent polishing, such as chemical mechanical polishing (CMP), and oxide removal operations in accordance with embodiments of the present invention. The oxide layer 160 can include the same or similar materials as the silicon oxide of the corresponding portions 114 and has an upper surface which is built up to a height well above upper surfaces of the OPL 150. As a result of the polishing and oxide removal operations, the OPL 150 and the oxide layer 160 are planarized such that their respective upper surfaces are coplanar with the respective upper surfaces of the corresponding portions 114. Thus, as shown in FIG. 14, the second repeating array 170 is generated.

The second repeating array 170 includes first vertical elements 171, second vertical elements 172 and third vertical elements 173. The first vertical elements 171 are formed of the material of the oxide layer 160 (i.e., silicon oxide), the second vertical elements 172 are formed of the material of the OPL 150 (i.e., organic substrate material) and the third vertical elements 173 are formed of the materials of the corresponding portions 115 and 116 (i.e., silicon nitride and amorphous silicon, respectively, where the silicon nitride effectively functions as a dielectric cap).

Each array 170′ of the repeating array 170 includes a single one of the first vertical elements 171, a pair of second vertical elements 172 abutting opposite sides of the single one of the first vertical elements 171 and a pair of third vertical elements 173 abutting respective exterior sides of each one of the pair of second vertical elements 172. The single one of the first vertical elements 171, each one of the pair of second vertical elements 172 and each one of the pair of third vertical elements 173 have a substantially similar height.

Each second vertical element 172 abuts in a side-by-side arrangement with a first vertical element 171 on one side thereof and abuts in a side-by-side arrangement with a third vertical element 173 on a second side thereof and the second repeating array 170 has a sub-30P or, more particularly, a 20P formation with improved critical dimension (CD) and pitch uniformity compared to its lithographically defined guiding pattern. That is, an edge of one of the second vertical elements 172 is less than 30 nm or, more particularly, 20 nm from an opposite edge of a neighboring first vertical element 171 and from an opposite edge of a neighboring second vertical element 173.

FIG. 15 depicts lithographic operations that allow for the precise removal of one or more of the first vertical elements 171 or one or more of the second vertical elements 172 from the second repeating array 170 of FIG. 14 in accordance with embodiments of the present invention.

As shown in FIG. 15, in an event one desired to preserve the first vertical elements 171₁ and 171₂ while etching the first vertical element 171₃, the lithographic operations include masking the first vertical elements 171₁ and 171₂ with masks 180, extending the masks 180 over the second vertical elements 172₁₁ and 172₁₂ and the second vertical elements 172₂₁ and 17₂₂ and extending the masks 180 over at least respective portions of the third vertical elements 173₁₁ and 173₁₂ and the third vertical elements 173₂₁ and 173₂₂. The masks 180 thus expose at least the first vertical element 171₃, its neighboring second vertical elements 172₃₁ and 172₃₂ and the respective portions of their neighboring third vertical elements 173₁₂ and 173₂₁. As such, an etch operation which is selective to the material of the first vertical elements 171 can be executed to etch the first vertical element 171₃ without correspondingly etching its neighboring second vertical elements 172₃₁ and 172₃₂, the respective portions of their neighboring third vertical elements 173₁₂ and 173₂₁ or any of the completely masked first, second and third vertical elements 171, 172 and 173.

Because the masks 180 of FIG. 15 are extended over the respective portions of the third vertical elements 173₁₁ and 173₁₂ and the third vertical elements 173₂₁ and 173₂₂, it is seen that the edges of the masks 180 are not required to be rectified with the edges of the second vertical elements 172₁₁ and 172₁₂ and the second vertical elements 172₂₁ and 17₂₂ in order for the first vertical element 171₃ to be selectively etched. This is due to the fact that the materials of the first, second and third vertical elements 171, 172 and 173 are selectively etchable with respect to one another.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched while the second element will have minimal loss during the etching process.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A wafer element with a tight fin-pitch formation, comprising:
an alternating material hard mask comprising a repeating array of abutting first, second and third vertical elements,
wherein:
the first, second and third vertical elements are formed of first, second and third materials, respectively,
the first material are selectively etchable with respect to the second and third materials,
the second material are selectively etchable with respect to the first and third materials, and
the third material are selectively etchable with respect to the first and second materials.

2. The wafer element according to claim 1 further comprising:
a silicon substrate; and
a dielectric layer disposed over the silicon substrate and on which the alternating material hard mask is disposed.

3. The wafer element according to claim 1, wherein:
The repeating array of the abutting first, second and third vertical elements are provided in a sub-30P formation, and
the sub-30P formation is characterized in that opposite edges of adjacent pairs of the first, second and third vertical elements are less than 30 nm apart.

4. The wafer element according to claim 1, wherein the first material comprises oxide, the second material comprises organic material and the third material comprises amorphous silicon.

5. The wafer element according to claim 1, wherein each array of the repeating array comprises:
a single one of the first vertical elements;
a pair of second vertical elements abutting opposite sides of the single one of the first vertical elements; and
a pair of third vertical elements abutting respective exterior sides of each one of the pair of second vertical elements.

6. The wafer element according to claim 5, wherein the single one of the first vertical elements, each one of the pair of second vertical elements and each one of the pair of third vertical elements have a substantially similar height.

7. A method of fabricating a wafer element with a tight-pitch formation, the method comprising:
assembling an initial structure comprising an alternating material hard mask stack, a fin array and a spacer material disposed over the fin array;
executing a self-aligned double patterning (SADP) process on the initial structure to produce a guide pattern for a directed self-assembly process (DSA);
executing the DSA process from the guide pattern to produce a first repeating array of abutting first and second vertical elements; and
synthesizing a second repeating array of abutting first, second and third vertical elements from the first repeating array.

8. The method according to claim 7, wherein:
the first repeating array of the abutting first and second vertical elements and the second repeating array of the abutting first, second and third vertical elements are each provided in a sub-30P formation, and
the sub-30P formations are each characterized in that opposite edges of adjacent pairs of the first and second or first, second and third vertical elements are less than 30 nm apart.

9. The method according to claim 7, wherein:
the first, second and third vertical elements of the second repeating array are formed of first, second and third materials, respectively,
the first material is selectively etchable with respect to the second and third materials,
the second material is selectively etchable with respect to the first and third materials, and
the third material is selectively etchable with respect to the first and second materials.

10. The method according to claim 7, wherein:
the first, second and third vertical elements of the second repeating array are formed of first, second and third materials, respectively, and
the first material comprises oxide, the second material comprises organic material and the third material comprises amorphous silicon.

11. The method according to claim 7, wherein each array of the second repeating array comprises:
a single one of the first vertical elements;
a pair of second vertical elements abutting opposite sides of the single one of the first vertical elements; and
a pair of third vertical elements abutting respective exterior sides of each one of the pair of second vertical elements.

12. The method according to claim 11, wherein the single one of the first vertical elements, each one of the pair of second vertical elements and each one of the pair of third vertical elements have a substantially similar height.

13. The method according to claim 7 further comprising:
masking at least one of the first, second and third vertical elements of the second repeating array;
extending the mask over another of the first, second and third vertical elements of the second repeating array;
extending the mask over at least a portion of yet another of the first, second and third vertical elements of the second repeating array; and
etching unmasked portions of the second repeating array.

14. A method of fabricating a wafer element with a tight-pitch formation, the method comprising:
assembling an initial structure comprising an alternating material hard mask stack, a fin array and a spacer material disposed over the fin array;
executing a self-aligned double patterning (SADP) process on the initial structure to produce a first intermediate structure comprising vertical elements, the vertical elements comprising vertical portions of the spacer material and corresponding portions of the alternating material hard mask stack;
executing a directed self-assembly (DSA) process on the first intermediate structure to produce a second intermediate structure comprising a first repeating array of abutting first and second vertical elements; and
synthesizing a second repeating array of abutting first, second and third vertical elements from the second intermediate structure.

15. The method according to claim 14, wherein:
the first repeating array of the abutting first and second vertical elements and the second repeating array of the abutting first, second and third vertical elements are each provided in a sub-30P formation, and
the sub-30P formations are each characterized in that opposite edges of adjacent pairs of the first and second or first, second and third vertical elements are less than 30 nm apart.

16. The method according to claim 14, wherein:
the first, second and third vertical elements of the second repeating array are formed of first, second and third materials, respectively,
the first material is selectively etchable with respect to the second and third materials,
the second material is selectively etchable with respect to the first and third materials, and
the third material is selectively etchable with respect to the first and second materials.

17. The method according to claim 14, wherein:
the first, second and third vertical elements of the second repeating array are formed of first, second and third materials, respectively, and
the first material comprises oxide, the second material comprises organic material and the third material comprises amorphous silicon.

18. The method according to claim 14, wherein each array of the second repeating array comprises:
a single one of the first vertical elements;
a pair of second vertical elements abutting opposite sides of the single one of the first vertical elements; and
a pair of third vertical elements abutting respective exterior sides of each one of the pair of second vertical elements.

19. The method according to claim 18, wherein the single one of the first vertical elements, each one of the pair of second vertical elements and each one of the pair of third vertical elements have a substantially similar height.

20. The method according to claim 14 further comprising:
masking at least one of the first, second and third vertical elements of the second repeating array;
extending the mask over another of the first, second and third vertical elements of the second repeating array;
extending the mask over at least a portion of yet another of the first, second and third vertical elements of the second repeating array; and
etching unmasked portions of the second repeating array.
